(19) United States
(12) Patent Application Publication
(10) Pub. No.: US 2025/0096773 A1
(43) Pub. Date: Mar. 20, 2025

(54) Bulk Acoustic Wave Resonance Assembly and Method for Manufacturing Same

(71) Applicant: Wuhan MEMSonics Technologies Co., Ltd., Wuhan (CN)

(72) Inventors: Jinhao DAI, Wuhan (CN); Kunli ZHAO, Wuhan (CN); Bensong Pi, Wuhan (CN); Humberto Campanella, Barcelona (ES); Hexin TENG, Wuhan (CN); Taixi LI, Seoul (KR); Yaping ZHOU, Wuhan (CN); Chao ZHAO, Wuhan (CN); Xiaoping WANG, Wuhan (CN); Jian WANG, Singapore (SG); Bowoon SOON, Singapore (SG); Chengliang SUN, Wuhan (CN)

(21) Appl. No.: 18/662,735

(22) Filed: May 13, 2024

(30) Foreign Application Priority Data
Sep. 14, 2023 (CN) 202311191406.8

(51) Int. Cl. H03H 9/205; H03H 3/02; H03H 9/13

(52) U.S. Cl. CPC H03H 9/205; H03H 3/02; H03H 9/132

(57) ABSTRACT

The present application discloses a bulk acoustic wave resonance assembly and a method for manufacturing the same. The bulk acoustic wave resonance assembly of the present application includes a substrate, a first resonance assembly and a second resonance assembly which are arranged on the substrate; an interconnection region is formed between the first resonance assembly and the second resonance assembly; the first resonance assembly includes a first bottom electrode, a first piezoelectric layer, and a first top electrode which are arranged on the substrate in sequence; the second resonance assembly includes a second bottom electrode, a second piezoelectric layer, and a second top electrode which are arranged on the substrate in sequence; the first bottom electrode and the second top electrode are connected to each other in the interconnection region; and the second bottom electrode and the first top electrode are connected to each other in the interconnection region.

### CROSS-REFERENCE TO RELATED APPLICATION

This application is filed based upon and claims priority to Chinese Patent Application No. 202311191406.8, filed on Sep. 14, 2023, the contents of which are hereby incorporated by reference in its entirety.

### TECHNICAL FIELD

The present application relates to the technical field of communications, and in particular, to a bulk acoustic wave resonance assembly and a method for manufacturing the same.

### BACKGROUND

A bulk acoustic wave filter is composed of a plurality of bulk acoustic wave resonators connected in series or in parallel. Each bulk acoustic wave resonator is prepared by longitudinal resonance of a piezoelectric thin film in a thickness direction. The bulk acoustic wave resonator has become a feasible alternative to a surface acoustic wave device and a quartz crystal resonator in mobile communications, high-speed serial data applications, and other aspects. Therefore, a radio frequency front-end thin film bulk acoustic wave filter/duplexer has superior filtering characteristics, such as low insertion loss, steep transition band, high anti-static discharge ability, and the like.

In order to improve the second harmonic suppression of the bulk acoustic wave filter, two centrosymmetric resonators that are in reverse parallel connection may be designed in a circuit, and a nonlinear effect of a device is weakened by the principle of phase cancellation. A specific connection manner is that a bottom electrode of one of the two bulk acoustic wave resonators is connected to a top electrode of the other bulk acoustic wave resonator, and a top electrode of one bulk acoustic wave resonator is connected to a bottom electrode of the other bulk acoustic wave resonator. In the existing technology, there are two specific technical solutions to achieve the reverse parallel connection of the resonators. In the first solution, the top electrode and the bottom electrode are led out of resonance regions of the two resonators for connection, thereby increasing the volume occupied by the device. In the second solution, through holes are formed in the piezoelectric ceramic thin films, and then metal is deposited in the through holes to turn on the top electrode and the bottom electrode. Due to the through holes, the connection effect between the top electrode and the bottom electrode is affected by depth to width ratios of the through holes and the quality of hole metallization, which may lead to unstable connections and introduce additional losses.

### SUMMARY

The present application provides a bulk acoustic wave resonance assembly and a method for manufacturing the same.

One aspect of an embodiment of the present application provides a bulk acoustic wave resonance assembly, including a substrate, and a first resonance assembly and a second resonance assembly which are arranged on the substrate, and an interconnection region is formed between the first resonance assembly and the second resonance assembly; the first resonance assembly includes a first bottom electrode, a first piezoelectric layer, and a first top electrode which are arranged on the substrate in sequence; the second resonance assembly includes a second bottom electrode, a second piezoelectric layer, and a second top electrode which are arranged on the substrate in sequence; the first bottom electrode and the second top electrode are connected to each other in the interconnection region; and the second bottom electrode and the first top electrode are connected to each other in the interconnection region.

As an embodiment, the first piezoelectric layer and the second piezoelectric layer are connected to each other in the interconnection region; at least two through grooves are formed in a piezoelectric layer in the interconnection region to form a plurality of connection regions; the first bottom electrode extends to at least one of the plurality of connection regions and is connected to the second top electrode to form a first connection; and the second bottom electrode extends to at least one of the plurality of connection regions and is connected to the first top electrode to form a second connection.

As an embodiment, the bulk acoustic wave resonance assembly includes a plurality of through grooves to form the plurality of connection regions; and at least one first connection and at least one second connection are formed in the plurality of connection regions.

As an embodiment, a quantity of first connections and a quantity of second connections are equal or have a difference of 1; and the first connections and the second connections are alternately arranged at intervals.

As an embodiment, the bulk acoustic wave resonance assembly includes three through grooves to form three connection regions; the first connection is located between two of the second connections; and a connection width of the first connection is greater than a connection width of each second connection.

As an embodiment, the bulk acoustic wave resonance assembly includes four through grooves to form four connection regions; and a connection width of each first connection is the same as a connection width of each second connection.

As an embodiment, the first piezoelectric layer and the second piezoelectric layer are separated from each other in the interconnection region; the first bottom electrode extends to the interconnection region and is connected to the second top electrode to form a third connection; the second bottom electrode extends to the interconnection region and is connected to the first top electrode to form a fourth connection; and the third connection is separated from the fourth connection.

As an embodiment, the first piezoelectric layer and the second piezoelectric layer are respectively provided with missing corners to expose a portion of the first bottom electrode and a portion of the second bottom electrode; the first top electrode extends to the missing corner of the second piezoelectric layer to form a first extension portion; the first extension portion is connected to the second bottom electrode; the second top electrode extends to the missing corner of the first piezoelectric layer to form a second extension portion; and the second extension portion is connected to the first bottom electrode.

As an embodiment, a width of the first extension portion in a extension direction of the first extension portion gradually decrease, and a width of the second extension portion in an extension direction of the second extension portion gradually decrease.

Another aspect of an embodiment of the present application provides a method for manufacturing a bulk acoustic wave resonance assembly, which is used for manufacturing the bulk acoustic wave resonance assembly described above, including: a substrate is provided, and a metal material is deposited on the substrate to form a bottom electrode layer; the bottom electrode layer is etched to form a first bottom electrode and a second bottom electrode, and a first trench is provided between the first bottom electrode and the second bottom electrode to separate the first bottom electrode from the second bottom electrode; a piezoelectric material is deposited on an etched bottom electrode layer to form a piezoelectric base layer; the piezoelectric base layer is etched to form a first piezoelectric layer and a second piezoelectric layer, and the first piezoelectric layer is located on the first bottom electrode, the second piezoelectric layer is located on the second bottom electrode, a second trench is provided between the first piezoelectric layer and the second piezoelectric layer to separate the first piezoelectric layer from the second piezoelectric layer, and the second trench is communicated to the first trench; a metal material is deposited on an etched piezoelectric base layer to form a top electrode layer, and the top electrode layer fills the first trench and the second trench; and the top electrode layer is etched to form a first top electrode and a second top electrode, and the first top electrode is located on the first piezoelectric layer; the second top electrode is located on the second piezoelectric layer; the first top electrode is connected to the second bottom electrode through the metal material in the first trench and the second trench; and the second top electrode is connected to the first bottom electrode through the metal material in the first trench and the second trench.

### BRIEF DESCRIPTION OF THE DRAWINGS

For clearer descriptions of the technical solutions of the embodiments of the present application, the drawings required to be used in the embodiments are briefly introduced below. It should be understood that the drawings below are only some embodiments of the present application. Therefore, the embodiments shall not be regarded as limitations on the scope. A person of ordinary skill in the art may also obtain other relevant drawings according to these drawings without creative work.

FIG. 1 is a schematic structural diagram I of a bulk acoustic wave resonance assembly according to an embodiment of present application;

FIG. 2 is a cross-sectional view of FIG. 1 along A-A;

FIG. 3 is a schematic structural diagram II of a bulk acoustic wave resonance assembly according to an embodiment of present application;

FIG. 4 is a schematic structural diagram Ill of a bulk acoustic wave resonance assembly according to an embodiment of present application;

FIG. 5 is a schematic structural diagram IV of a bulk acoustic wave resonance assembly according to an embodiment of present application;

FIG. 6 is a flowchart of a method for manufacturing a bulk acoustic wave resonance assembly according to an embodiment of the present application; and

FIG. 7 and FIG. 8 are schematic structural diagrams of a method for manufacturing a bulk acoustic wave resonance assembly according to an embodiment of the present application after all process steps.

### DETAILED DESCRIPTION OF THE EMBODIMENTS

In order to make the objectives, technical solutions, and advantages of the embodiments of the present application clearer, the technical solutions in the embodiments of the present application are clearly and completely described below with reference to the accompanying drawings in the embodiments of the present application. Apparently, the described embodiments are merely some rather than all of the embodiments of the present application. Assemblies of the embodiments of the present application commonly described and shown in the accompanying drawings here may be arranged and designed in a variety of different configurations.

Accordingly, the following detailed descriptions of the embodiments of the present application provided in the accompanying drawings are not intended to limit the scope of the claimed present application, but merely represents selected embodiments of the present application. All other embodiments obtained by a person of ordinary skill in the art based on the embodiments of the present application without making creative efforts shall fall within the protection scope of the present application.

It should be noted that similar reference numerals and letters indicate similar items in the following drawings. Therefore, once a certain item is defined in one drawing, it is unnecessary to further define and explain it in the subsequent drawings. In addition, the terms “first”, “second”, “third”, and the like are only for the purpose of description, and may not be understood as indicating or implying the relative importance.

In the description of the present application, it should also be noted that unless otherwise specified and limited, the terms “arrange”, “mount”, “connection”, and “connected” should be interpreted broadly. A person of ordinary skill in the art may understand the specific meanings of the above terms in the present disclosure according to specific situations.

In order to suppress second harmonics of a bulk acoustic wave resonator, resonators that are in reverse parallel connection are arranged in a filter, and the principle of phase cancellation is used to weaken the nonlinear effect of a device.

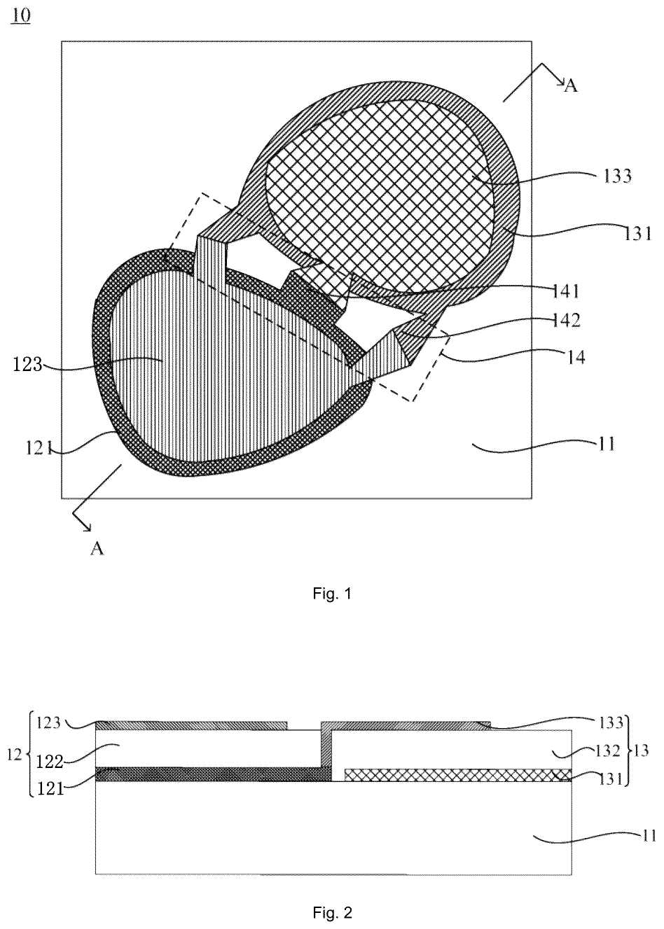

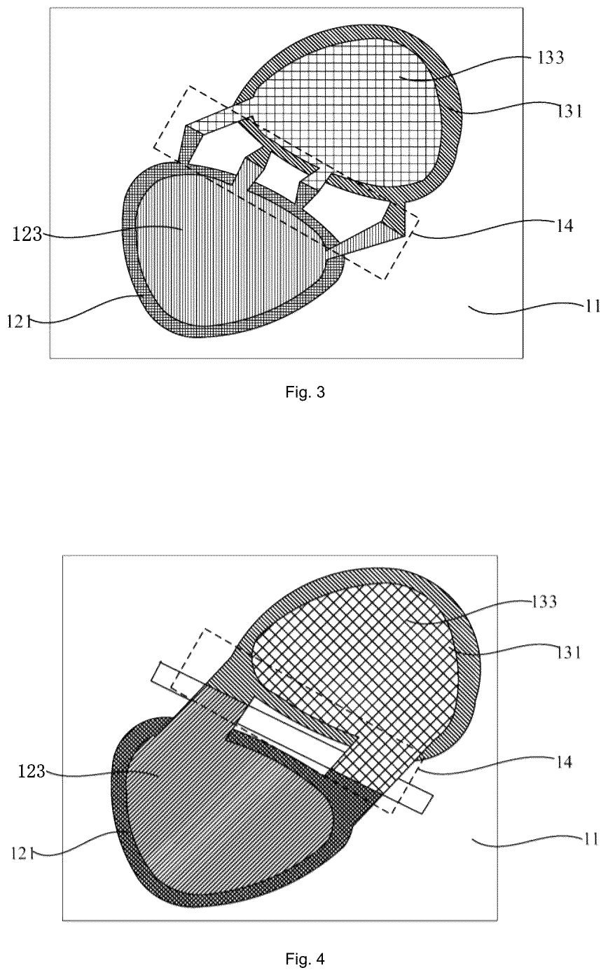

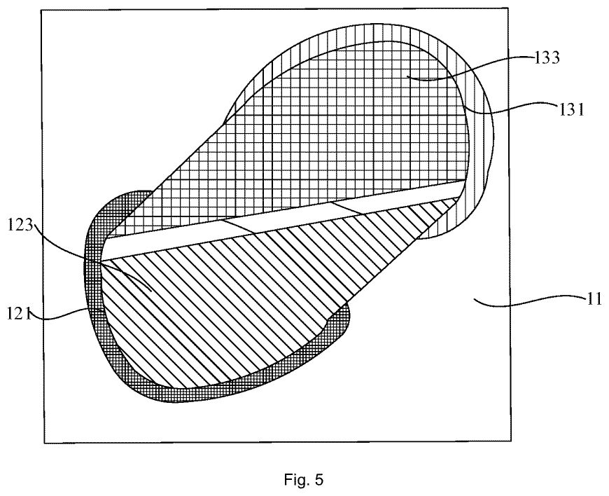

An embodiment of the present application provides a bulk acoustic wave resonance assembly 10, as shown in FIG. 1, FIG. 2, FIG. 3, FIG. 4, and FIG. 5, including a substrate 11, and a first resonance assembly 12 and a second resonance assembly 13 which are arranged on the substrate 11. An interconnection region 14 is formed between the first resonance assembly 12 and the second resonance assembly 13; the first resonance assembly 12 includes a first bottom electrode 121, a first piezoelectric layer 122, and a first top electrode 123 which are arranged on the substrate 11 in sequence; the second resonance assembly 13 includes a second bottom electrode 131, a second piezoelectric layer 132, and a second top electrode 133 which are arranged on the substrate 11 in sequence; the first bottom electrode 121 and the second top electrode 133 are connected to each other in the interconnection region 14; and the second bottom electrode 131 and the first top electrode 123 are connected to each other in the interconnection region 14.

The bulk acoustic wave resonance assembly 10 provided by this embodiment of the present application is applied to a filter. The principle of phase cancellation is used to weaken the nonlinear effect of the filter. Specifically, the bulk acoustic wave resonance assembly 10 of the present application includes a substrate 11 and a first resonance assembly 12 and a second resonance assembly 13 which are arranged on the substrate 11. A top electrode of the first resonance assembly 12 is connected to a bottom electrode of the second resonance assembly 13, and a bottom electrode of the first resonance assembly 12 is connected to a top electrode of the second resonance assembly 13. Specifically, the first resonance assembly 12 includes a first bottom electrode 121, a first piezoelectric layer 122, and a first top electrode 123 which are arranged on the substrate 11 in sequence, and the second resonance assembly 13 includes a second bottom electrode 131, a second piezoelectric layer 132, and a second top electrode 133 which are arranged on the substrate 11 in sequence. In order to achieve an effect of weakening the nonlinearity of the filter by connecting the first bottom electrode 121 to the second top electrode 133 and connecting the first top electrode 123 to the second bottom electrode 131, in this embodiment of the present application, an interconnection region 14 is arranged between the first resonance assembly 12 and the second resonance assembly 13. The first bottom electrode 121 and the second top electrode 133 are connected to each other in the interconnection region 14, and the second bottom electrode 131 and the first top electrode 123 are connected to each other in the interconnection region 14. As the interconnection region 14 is arranged between the first resonance assembly 12 and the second resonance assembly 13, an increase in the volume of the bulk acoustic wave resonance assembly 10 caused by leading the interconnection region outward is avoided. The interconnection region 14 is located between the first resonance assembly 12 and the second resonance assembly 13, so that the interconnection region 14 has a large area. In this way, the connection between the first bottom electrode 121 and the second top electrode 133 and the connection between the second bottom electrode 131 and the first top electrode 123 both have large areas, and extra loss introduced by unstable connection between the two resonance assemblies is avoided. Therefore, the bulk acoustic wave resonance assembly 10 provided by the embodiments of the present application may improve the stability of reverse parallel connection and reduce the loss on the basis of not increasing the volume of the bulk acoustic wave resonance assembly 10.

In addition, a region where the first top electrode 123, the first piezoelectric layer 122, and the first bottom electrode 121 overlap is a first effective resonance region; a region where the second top electrode 133, the second piezoelectric layer 132, and the second bottom electrode 131 overlap is a second effective resonance region; and a specific shape of each of the first effective resonance region and the second effective resonance region is not specifically limited, which may be a regular polygon, an irregular polygon, a circle, a closed pattern formed by a plurality of curved edges, or the like. In some embodiments, as shown in FIG. 1, the shape is the closed pattern formed by the plurality of curved edges. In addition, in order to improve the vibration efficiency of the first effective resonance region and the vibration efficiency of the second effective resonance region, cavities may be arranged on the substrate 11 corresponding to the first effective resonance region and the second effective resonance region.

The bulk acoustic wave resonance assembly 10 provided by the present application includes the substrate 11, and the first resonance assembly 12 and the second resonance assembly 13 which are arranged on the substrate 11, and the interconnection region 14 is formed between the first resonance assembly 12 and the second resonance assembly 13. By the arrangement of the interconnection region 14 between the first resonance assembly 12 and the second resonance assembly 13, the top electrode and the bottom electrode of the two resonance assemblies are interconnected between the first resonance assembly 12 and the second resonance assembly 13, which avoids the increase in the volume of the bulk acoustic wave resonance assembly 10 caused by leading the interconnection region outward. The first resonance assembly 12 includes the first bottom electrode 121, the first piezoelectric layer 122, and the first top electrode 123 which are arranged on the substrate 11 in sequence; the second resonance assembly 13 includes the second bottom electrode 131, the second piezoelectric layer 132, and the second top electrode 133 which are arranged on the substrate 11 in sequence; the first bottom electrode 121 and the second top electrode 133 are connected to each other in the interconnection region 14; and the second bottom electrode 131 and the first top electrode 123 are connected to each other in the interconnection region 14. The interconnection region 14 is located between the first resonance assembly 12 and the second resonance assembly 13, so that the interconnection region 14 has a large area. In this way, the connection between the first bottom electrode 121 and the second top electrode 133 and the connection between the second bottom electrode 131 and the first top electrode 123 both have large areas, and extra loss introduced by unstable connection between the two resonance assemblies is avoided. Therefore, the bulk acoustic wave resonance assembly 10 provided by the embodiments of the present application may improve the stability of reverse parallel connection and reduce the loss on the basis of not increasing the volume of the bulk acoustic wave resonance assembly 10.

In some embodiments, an edge of an orthographic projection of at least one of the first bottom electrode 121 and the second bottom electrode 131 on the substrate 11 is a curve. An edge of an orthographic projection of at least one of the first top electrode 123 and the second top electrode 133 on the substrate 11 is a curve. An edge of an orthographic projection of at least one of the first piezoelectric layer 122 and the second piezoelectric layer 132 on the substrate 11 is a curve.

As shown in FIG. 1, FIG. 3, and FIG. 4, a projection of the first bottom electrode 121 on the substrate 11 is a water droplet-like structure, which is enclosed by a curve. A projection of the second bottom electrode 131 on the substrate 11 is a water droplet-like structure, which is enclosed by a curve. Similarly, a projection of the first top electrode 123 on the substrate 11 is a water droplet-like structure, which is enclosed by a curve. A projection of the second top electrode 133 on the substrate 11 is a water droplet-like structure, which is enclosed by a curve. A projection of the first piezoelectric layer 122 (not shown in FIG. 1, FIG. 3, and FIG. 4) on the substrate 11 is a water droplet-like structure, which is enclosed by a curve. A projection of the second piezoelectric layer 132 (not shown in FIG. 1, FIG. 3, and FIG. 4) on the substrate 11 is a water droplet-like structure, which is enclosed by a curve.

In another optional solution, an orthographic projection of at least one of the first top electrode 123 and the second top electrode 133 on the substrate 11 is enclosed by a curve and a straight line. Based on this, the orthographic projections of the first bottom electrode 121 and the second bottom electrode 131 on the substrate 11 may be enclosed by the curve or the curve and the straight line. Similarly, the orthographic projections of the first piezoelectric layer 122 and the second piezoelectric layer 132 on the substrate 11 may be enclosed by the curve or the curve and the straight line.

FIG. 5 exemplarily shows an embodiment where orthographic projections of the first top electrode and the second top electrode on the substrate are enclosed by a curve and a straight line, and orthographic projections of the first bottom electrode and the second bottom electrode on the substrate are enclosed by a curve.

In some embodiments, as shown in FIG. 1 and FIG. 3, the first piezoelectric layer 122 and the second piezoelectric layer 132 are connected to each other in the interconnection region 14; at least two through grooves are formed in a piezoelectric layers in the interconnection region 14 to form a plurality of connection regions; the first bottom electrode 121 extends to at least one of the plurality of connection regions and is connected to the second top electrode 133 to form a first connection 141, and the first connection 141 represents a first connection structure; and the second bottom electrode 131 extends to at least one of the plurality of connection regions and is connected to the first top electrode 123 to form a second connection 142, and the second connection 142 represents a second connection structure.

The plurality of connection regions are formed in the interconnection region 14. The plurality of connection regions are respectively configured to connect the first top electrode 123 to the second bottom electrode 131, as well as the second top electrode 133 to the first bottom electrode 121, so that the first top electrode 123 and the second bottom electrode 131 are connected to each other through a plurality of second connections 142, and the first bottom electrode 121 and the second top electrode 133 are connected to each other through a plurality of first connections 141. The plurality of connections make the connection between the two resonance assemblies in the bulk acoustic wave resonance assembly 10 stable.

In an implementation of this embodiment of the present application, as shown in FIG. 1 and FIG. 3, the bulk acoustic wave resonance assembly 10 includes a plurality of through grooves to form a plurality of connection regions; and the plurality of connection regions form at least one first connection 141 and at least one second connection 142.

In some embodiments, as shown in FIG. 1 and FIG. 3, a quantity of first connections 141 and a quantity of second connections 142 are equal or have a difference of 1; and the first connections 141 and the second connections 142 are alternately arranged at intervals.

The quantity of the first connections 141 and the quantity of the second connections 142 are set to be the same or have a difference of 1, and the first connections 141 and the second connections 142 are alternately arranged at intervals, so that the first connections 141 and second connections 142 are uniformly distributed in the interconnection region 14, facilitating transmission of electrical signals between the top electrode and the bottom electrode.

In an implementation of this embodiment of the present application, as shown in FIG. 1, the bulk acoustic wave resonance assembly 10 includes three through grooves to form three connection regions; the first connection 141 is located between two of the second connections 142; and a connection width of the first connection 141 is greater than a connection width of each second connection 142, and the connection width of the first connection 141 is a width of a connection line connecting the first bottom electrode 121 and the second top electrode 133, the connection width of the second connection 142 is a width of a connection line connecting the first top electrode 123 and the second bottom electrode 131.

If there are excessive connection regions, it is difficult to operate a manufacturing process of the bulk acoustic wave resonance assembly 10. In this embodiment of the present application, considering both the connection stability and the manufacturing difficulty, three through grooves are arranged in the interconnection region 14 to form three connection regions, including one first connection 141 and two second connections 142. The first connection 141 is located between the two second connections 142. In order to improve the connection stability, the first connection 141 with the small quantity is set to be wider, that is, the connection width of the first connection 141 is greater than that of each of the second connections 142.

In some embodiments, as shown in FIG. 3, the bulk acoustic wave resonance assembly 10 includes four through grooves to form four connection regions. A width of the first connection 141 and a width of the second connection 142 are the same.

In some embodiments, four connection regions may also be provided to form four connection regions, including two first connections 141 and two second connections 142. When the quantity of the first connections 141 and the quantity of the second connections 142 are the same, widths of the first connections 141 and widths of the second connections 142 may be set to be the same.

In an implementation of this embodiment of the present application, as shown in FIG. 4, the first piezoelectric layer 122 and the second piezoelectric layer 132 are separated from each other in the interconnection region 14. The first bottom electrode 121 extends to the interconnection region 14 and is connected to the second top electrode 133 to form a third connection. The third connection represents a third connection structure. The second bottom electrode 131 extends to the interconnection region 14 and is connected to the first top electrode 123 to form a fourth connection. The fourth connection represents a fourth connection structure. The third connection and the fourth connection are separated from each other.

In order to facilitate manufacturing of a bulk acoustic wave resonator, the first piezoelectric layer 122 and the second piezoelectric layer 132 are completely separated from each other in the interconnection region 14. In this way, only a large through groove is required. The first bottom electrode 121 extends into the through groove and is connected to the second top electrode 133 to form the third connection, and the second bottom electrode 131 extends into the through groove and is connected to the first top electrode 123 to form the fourth connection. The third connection and the fourth connection are separated from each other. The manufacturing difficulty of the large through groove is relatively low.

In some embodiments, as shown in FIG. 5, the first piezoelectric layer 122 and the second piezoelectric layer 132 are respectively provided with missing corners to expose a portion of the first bottom electrode 121 and a portion of the second bottom electrode 131, and the missing corner of the first piezoelectric layer 122 exposes the portion of the first bottom electrode 121, the missing corner of the second piezoelectric layer 132 exposes the portion of the second bottom electrode 131; the first top electrode 123 extends to the missing corner of the second piezoelectric layer 132 to form a first extension portion; the first extension portion is connected to the second bottom electrode 131; the second top electrode 133 extends to the missing corner of the first piezoelectric layer 122 to form a second extension portion; and the second extension portion is connected to the first bottom electrode 121.

The first piezoelectric layer 122 and the second piezoelectric layer 132 are provided with the missing corners to expose the first bottom electrode 121 and the second bottom electrode 131. Furthermore, the first top electrode 123 extends to the missing corner of the second piezoelectric layer 132, so that the first top electrode 123 is connected to the second bottom electrode 131. Similarly, the second top electrode 133 extends to the missing corner of the first piezoelectric layer 122, so that the second top electrode 133 is connected to the first bottom electrode 121.

By the extension of the first top electrode 123 and the second top electrode 133, a connection area of the top electrode and the bottom electrode may be enlarged, and the loss may be reduced.

In an implementation of this embodiment of the present application, as shown in FIG. 5, widths of the first extension portion and the second extension portion in extension directions of the first extension portion and the second extension portion gradually decrease.

The widths of the first extension portion and the second extension portion in their extension directions gradually decrease. On the one hand, a contact area between the first top electrode 123 and the second bottom electrode 131, and a contact area between the second top electrode 133 and the first bottom electrode 121 may be enlarged; and on the other hand, gradually changing the widths may make the electrical connection more stable.

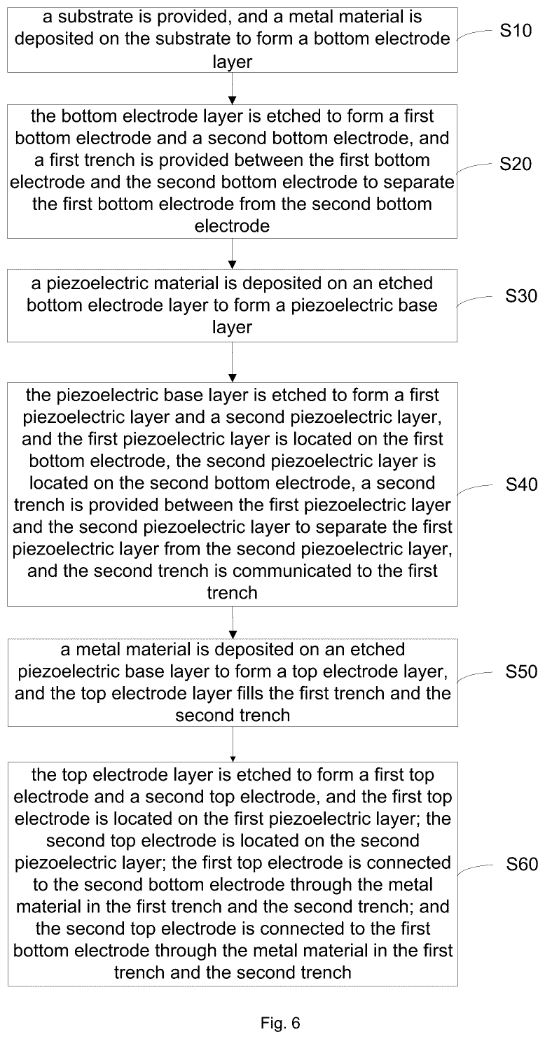

Another aspect of an embodiment of the present application provides a method for manufacturing a bulk acoustic wave resonance assembly 10, which is used for manufacturing the bulk acoustic wave resonance assembly 10 described above, as shown in FIG. 6, including:

S10: a substrate 11 is provided, and a metal material is deposited on the substrate 11 to form a bottom electrode layer;

A specific material of the substrate 11 and a specific material of the metal material are not limited in this embodiment of the present application, and a substrate 11 and electrode materials which are commonly used in a resonator may be used.

S20: the bottom electrode layer is etched to form a first bottom electrode 121 and a second bottom electrode 131, and a first trench is provided between the first bottom electrode 121 and the second bottom electrode 131 to separate the first bottom electrode 121 from the second bottom electrode 131;

S30: a piezoelectric material is deposited on an etched bottom electrode layer to form a piezoelectric base layer.

S40: the piezoelectric base layer is etched to form a first piezoelectric layer 122 and a second piezoelectric layer 132, and the first piezoelectric layer 122 is located on the first bottom electrode 121, the second piezoelectric layer 132 is located on the second bottom electrode 131, a second trench is provided between the first piezoelectric layer 122 and the second piezoelectric layer 132 to separate the first piezoelectric layer 122 from the second piezoelectric layer 132, and the second trench is communicated to the first trench;

S50: a metal material is deposited on an etched piezoelectric base layer to form a top electrode layer, and the top electrode layer fills the first trench and the second trench;

S60: the top electrode layer is etched to form a first top electrode 123 and a second top electrode 133, and the first top electrode 123 is located on the first piezoelectric layer 122; the second top electrode 133 is located on the second piezoelectric layer 132; the first top electrode 123 is connected to the second bottom electrode 131 through the metal material in the first trench and the second trench; and the second top electrode 133 is connected to the first bottom electrode 121 through the metal material in the first trench and the second trench.

It should be noted that the first trench and the second trench may also be formed in the same step, that is, the piezoelectric material is deposited on the bottom electrode layer before the bottom electrode layer is etched, and the first trench and the second trench may be formed in one etching.

The bulk acoustic wave resonance assembly 10 manufactured by the method for manufacturing the bulk acoustic wave resonance assembly 10 provided by the embodiments of the present application may improve the stability of reverse parallel connection and reduce the loss on the basis of not increasing the volume of the bulk acoustic wave resonance assembly 10.

Still another aspect of an embodiment of the present application provides a method for manufacturing a bulk acoustic wave resonance assembly 10, which is used for manufacturing the bulk acoustic wave resonance assembly 10 described above, including:
step S11: as shown in FIG. 2, a substrate 11 is provided, and a first bottom electrode 121 and a second bottom electrode 131 are formed on the substrate 11, and the first bottom electrode 121 and the second bottom electrode 131 are separated;

A specific material of the substrate 11 is not limited in this embodiment of the present application, and a substrate 11 which is commonly used in a resonator may be used.
step S21: a first piezoelectric layer 122 is formed on the first bottom electrode 121, and a second piezoelectric layer 132 is formed on the second bottom electrode 131, and the first piezoelectric layer 122 and the second piezoelectric layer 132 are separated;
step S31: a first top electrode 123 connected to the second bottom electrode 131 is formed on the first piezoelectric layer 122, and a second top electrode 133 connected to the first bottom electrode 121 is formed on the second piezoelectric layer 132.

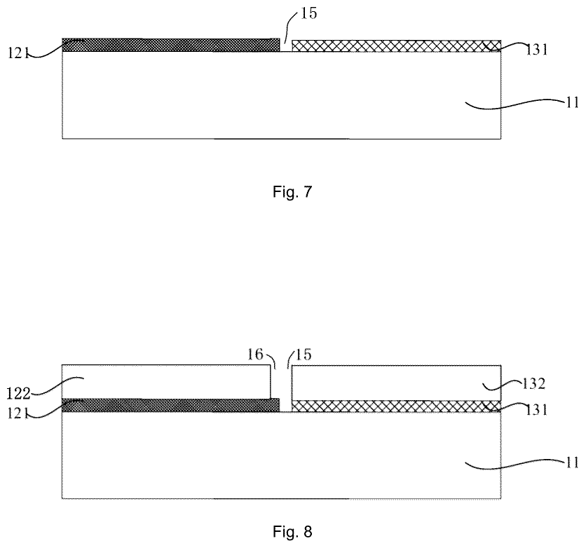

Further, as shown in FIG. 7, the first bottom electrode 121 and the second bottom electrode 131 are formed on the substrate 11, which includes:
a metal material is deposited on the substrate 11 to form a bottom electrode layer;

A specific material of the metal material is not limited in this embodiment of the present application, and electrode materials which are commonly used in a resonator may be used.
the bottom electrode layer is etched to form the first bottom electrode 121 and the second bottom electrode 131, and a first trench 15 is provided between the first bottom electrode 121 and the second bottom electrode 131 to separate the first bottom electrode 121 from the second bottom electrode 131.

As shown in FIG. 8, the first piezoelectric layer 122 is formed on the first bottom electrode 121, and the second piezoelectric layer 132 is formed on the second bottom electrode 131, which includes:
a piezoelectric material is deposited on an etched bottom electrode layer to form a piezoelectric base layer; and
the piezoelectric base layer is etched to form the first piezoelectric layer 122 and the second piezoelectric layer 132, and a second trench 16 is provided between the first piezoelectric layer 122 and the second piezoelectric layer 132 to separate the first piezoelectric layer 122 from the second piezoelectric layer 132, and the second trench 16 is communicated to the first trench 15.

As shown in FIG. 2, the first top electrode 123 connected to the second bottom electrode 131 is formed on the first piezoelectric layer 122, and the second top electrode 133 connected to the first bottom electrode 121 is formed on the second piezoelectric layer 132, which includes:
a metal material is deposited on an etched piezoelectric base layer to form a top electrode layer, and the top electrode layer fills the first trench 15 and the second trench 16; and
the top electrode layer is etched to form the first top electrode 123 and the second top electrode 133, and the first top electrode 123 is connected to the second bottom electrode 131 through the metal material in the first trench 15 and the second trench 16, and the second top electrode 133 is connected to the first bottom electrode 121 through the metal material in the first trench 15 and the second trench 16.

It should be noted that the first trench and the second trench may also be formed in the same step, that is, the piezoelectric material is deposited on the bottom electrode layer before the bottom electrode layer is etched, and the first trench and the second trench may be formed in one etching.

Beneficial effects of the embodiments of the present application include:

The bulk acoustic wave resonance assembly provided by the present application includes a substrate, and a first resonance assembly and a second resonance assembly which are arranged on the substrate, and an interconnection region is formed between the first resonance assembly and the second resonance assembly. By the arrangement of the interconnection region between the first resonance assembly and the second resonance assembly, the top electrode and the bottom electrode of the two resonance assemblies are interconnected between the first resonance assembly and the second resonance assembly, which avoids an increase in the volume of the bulk acoustic wave resonance assembly caused by leading the interconnection region outward. The first resonance assembly includes a first bottom electrode, a first piezoelectric layer, and a first top electrode which are arranged on the substrate in sequence; the second resonance assembly includes a second bottom electrode, a second piezoelectric layer, and a second top electrode which are arranged on the substrate in sequence; the first bottom electrode and the second top electrode are connected to each other in the interconnection region; and the second bottom electrode and the first top electrode are connected to each other in the interconnection region. The first bottom electrode and the second top electrode are connected to each other in the interconnection region, and the second bottom electrode and the first top electrode are connected to each other in the interconnection region. The interconnection region is located between the first resonance assembly and the second resonance assembly, so that the interconnection region has a large area. In this way, the connection between the first bottom electrode and the second top electrode and the connection between the second bottom electrode and the first top electrode both have large areas, and extra loss introduced by unstable connection between the two resonance assemblies is avoided. Therefore, the bulk acoustic wave resonance assembly provided by the embodiments of the present application may improve the stability of reverse parallel connection and reduce the loss on the basis of not increasing the volume of the bulk acoustic wave resonance assembly.

The above descriptions are only preferred embodiments of the present application, and are not intended to limit the present application. For those skilled in the art, the present application may have various modifications and changes. Any modification, equivalent replacement, and improvement made within the spirit and scope of the present application shall fall within the protection scope of the present application.

What is claimed is:

1. A bulk acoustic wave resonance assembly, comprising a substrate, and a first resonance assembly and a second resonance assembly which are arranged on the substrate, wherein an interconnection region is formed between the first resonance assembly and the second resonance assembly; the first resonance assembly comprises a first bottom electrode, a first piezoelectric layer, and a first top electrode which are arranged on the substrate in sequence; the second resonance assembly comprises a second bottom electrode, a second piezoelectric layer, and a second top electrode which are arranged on the substrate in sequence; the first bottom electrode and the second top electrode are connected to each other in the interconnection region; and the second bottom electrode and the first top electrode are connected to each other in the interconnection region.

2. The bulk acoustic wave resonance assembly as claimed in claim 1, wherein the first piezoelectric layer and the second piezoelectric layer are connected to each other in the interconnection region; at least two through grooves are formed in a piezoelectric layer in the interconnection region to form a plurality of connection regions; the first bottom electrode extends to at least one of the plurality of connection regions and is connected to the second top electrode to form a first connection; and the second bottom electrode extends to at least one of the plurality of connection regions and is connected to the first top electrode to form a second connection.

3. The bulk acoustic wave resonance assembly as claimed in claim 2, wherein the bulk acoustic wave resonance assembly comprises a plurality of through grooves to form the plurality of connection regions; and at least one first connection and at least one second connection are formed in the plurality of connection regions.

4. The bulk acoustic wave resonance assembly as claimed in claim 3, wherein a quantity of first connections and a quantity of second connections are equal or have a difference of 1; and the first connections and the second connections are alternately arranged at intervals.

5. The bulk acoustic wave resonance assembly as claimed in claim 4, wherein the bulk acoustic wave resonance assembly comprises three through grooves to form three connection regions; the first connection is located between two of the second connections; and a connection width of the first connection is greater than a connection width of each second connection.

6. The bulk acoustic wave resonance assembly as claimed in claim 4, wherein the bulk acoustic wave resonance assembly comprises four through grooves to form four connection regions; and a connection width of each first connection is the same as a connection width of each second connection.

7. The bulk acoustic wave resonance assembly as claimed in claim 1, wherein the first piezoelectric layer and the second piezoelectric layer are separated from each other in the interconnection region; the first bottom electrode extends to the interconnection region and is connected to the second top electrode to form a third connection; the second bottom electrode extends to the interconnection region and is connected to the first top electrode to form a fourth connection; and the third connection is separated from the fourth connection.

8. The bulk acoustic wave resonance assembly as claimed in claim 1, wherein the first piezoelectric layer and the second piezoelectric layer are respectively provided with missing corners to expose a portion of the first bottom electrode and a portion of the second bottom electrode; the first top electrode extends to the missing corner of the second piezoelectric layer to form a first extension portion; the first extension portion is connected to the second bottom electrode; the second top electrode extends to the missing corner of the first piezoelectric layer to form a second extension portion; and the second extension portion is connected to the first bottom electrode.

9. The bulk acoustic wave resonance assembly as claimed in claim 8, wherein a width of the first extension portion in a extension direction of the first extension portion gradually decrease, and a width of the second extension portion in a extension direction of the second extension portion gradually decrease.

10. The bulk acoustic wave resonance assembly as claimed in claim 1, wherein an edge of an orthographic projection of at least one of the first bottom electrode and the second bottom electrode on the substrate is a curve.

11. The bulk acoustic wave resonance assembly as claimed in claim 1, wherein an edge of an orthographic projection of at least one of the first top electrode and the second top electrode on the substrate is a curve.

12. The bulk acoustic wave resonance assembly as claimed in claim 1, wherein an edge of an orthographic projection of at least one of the first piezoelectric layer and the second piezoelectric layer on the substrate is a curve.

13. The bulk acoustic wave resonance assembly as claimed in claim 1, wherein an orthographic projection of at least one of the first top electrode and the second top electrode on the substrate is enclosed by a curve and a straight line.

14. The bulk acoustic wave resonance assembly as claimed in claim 1, wherein a region where the first top electrode, the first piezoelectric layer, and the first bottom electrode overlap is a first effective resonance region; a region where the second top electrode, the second piezoelectric layer, and the second bottom electrode overlap is a second effective resonance region; and a shape of each of the first effective resonance region and the second effective resonance region is one of: a regular polygon, an irregular polygon, a circle, and a closed pattern formed by a plurality of curved edges.

15. A method for manufacturing a bulk acoustic wave resonance assembly, which is used for manufacturing the bulk acoustic wave resonance assembly as claimed in claim 1, comprising:
providing a substrate, and forming a first bottom electrode and a second bottom electrode on the substrate, wherein the first bottom electrode and the second bottom electrode are separated;
forming a first piezoelectric layer on the first bottom electrode, and forming a second piezoelectric layer on the second bottom electrode, wherein the first piezoelectric layer and the second piezoelectric layer are separated; and
forming a first top electrode connected to the second bottom electrode on the first piezoelectric layer, and forming a second top electrode connected to the first bottom electrode on the second piezoelectric layer.

16. The method as claimed in claim 15, wherein forming the first bottom electrode and the second bottom electrode on the substrate comprises:
depositing a metal material on the substrate to form a bottom electrode layer; and
etching the bottom electrode layer to form the first bottom electrode and the second bottom electrode, wherein a first trench is provided between the first bottom electrode and the second bottom electrode to separate the first bottom electrode from the second bottom electrode.

17. The method as claimed in claim 16, wherein forming the first piezoelectric layer on the first bottom electrode, and forming the second piezoelectric layer on the second bottom electrode comprises:
depositing a piezoelectric material on an etched bottom electrode layer to form a piezoelectric base layer; and
etching the piezoelectric base layer to form the first piezoelectric layer and the second piezoelectric layer, wherein a second trench is provided between the first piezoelectric layer and the second piezoelectric layer to separate the first piezoelectric layer from the second piezoelectric layer, and the second trench is communicated to the first trench.

18. The method as claimed in claim 17, wherein forming the first top electrode connected to the second bottom electrode on the first piezoelectric layer, and forming the second top electrode connected to the first bottom electrode on the second piezoelectric layer comprises:
depositing a metal material on an etched piezoelectric base layer to form a top electrode layer, wherein the top electrode layer fills the first trench and the second trench; and
etching the top electrode layer to form the first top electrode and the second top electrode, wherein the first top electrode is connected to the second bottom electrode through the metal material in the first trench and the second trench, and the second top electrode is connected to the first bottom electrode through the metal material in the first trench and the second trench.
